(19) United States
(12) Patent Application Publication
(10) Pub. No.: US 2022/0157999 A1
(43) Pub. Date: May 19, 2022

(54) SEMICONDUCTOR DEVICE

(71) Applicant: RENESAS ELECTRONICS CORPORATION, Tokyo (JP)

(72) Inventor: Yanzhe WANG, Tokyo (JP)

(21) Appl. No.: 17/507,250

(22) Filed: Oct. 21, 2021

(30) Foreign Application Priority Data
Nov. 16, 2020 (JP) 2020-189964

(51) Int. Cl. H01L 29/792; H01L 29/423; H01L 29/40; H01L 29/51; H01L 29/66; H01L 21/28

(52) U.S. Cl. CPC H01L 29/792; H01L 29/42344; H01L 29/408; H01L 29/40117; H01L 29/517; H01L 29/518; H01L 29/66833; H01L 29/513

(57) ABSTRACT

A memory gate is formed on a semiconductor substrate via an insulating film that is a gate insulator for a memory element. The insulating film includes a first insulating film, a second insulating film on the first insulating film, a third insulating film on the second insulating film, and a fourth insulating film on the third insulating film. The second insulating film is an insulating film having a charge-accumulating function. A bandgap of each of the first insulating film and the third insulating film is larger than that of the second insulating film. The third insulating film is formed of a high dielectric constant material containing a metal element and oxygen. The fourth insulating film is a silicon oxide film or a silicon oxynitride film and is adjacent to the memory gate electrode.

### CROSS-REFERENCE TO RELATED APPLICATION

The disclosure of Japanese Patent Application No. 2020-189964 filed on Nov. 16, 2020, including the specification, drawings and abstract is hereby incorporated by reference in its entirety.

### BACKGROUND

The present invention relates to a semiconductor device and is suitable for, for example, a semiconductor device including a memory element.

As a non-volatile semiconductor memory device that is electrically erasable and programmable, EEPROM (electrically erasable and programmable read only memory) has been widely used.

There are disclosed techniques listed below. Memory devices represented by flash memory that is currently widely used include a floating gate electrode or a trap insulating film that is conductive and surrounded by an oxide film under a gate electrode of a MISFET (metal insulator semiconductor field effect transistor), in which a charge accumulating state in the floating gate or trap insulating film is used as memory information and that is read as a threshold value of the transistor. This trap insulating film is an insulating film that is capable of accumulating charges and a silicon nitride film is an example. By shifting a threshold value of a MISFET by injection and release of charges into and from such a charge accumulating region, an operation of a memory element is done. As compared with a case of using a conductive floating gate film as a charge accumulating region, there are such merits as reliability of data retention is better because charges are discretely accumulated, thicknesses of oxide films above and below the silicon nitride film can be thinner because of the better reliability in date retention, and a voltage for programming and erasing can be lowered.

[Patent Document 1] Japanese Unexamined Patent Application Publication No. 2019-91820.

Patent Document 1 discloses a technique relating to a semiconductor device including a memory element.

### SUMMARY

Improvements in performance of a semiconductor device including a memory element are desired.

Other problems and novel characteristics will be apparent from the description of the present specification and the attached drawings.

According to an embodiment, the semiconductor device includes a semiconductor substrate, and a first gate electrode formed through the first gate insulating film on the semiconductor substrate. The first gate insulating layer includes a first insulating layer, a second insulating layer on the first insulating layer, a third insulating layer on the second insulating layer, and a fourth insulating layer on the third insulating layer. The second insulating film is an insulating film having a charge accumulation function, each band gap of the first insulating film and the third insulating film is larger than a band gap of the second insulating film. The third insulating film is made of a high dielectric constant material containing a metal element and oxygen. The fourth insulating film is a silicon oxide film or a silicon oxynitride film, and is adjacent to the first gate electrode.

According to an embodiment, it is possible to improve the performance of the semiconductor device.

### BRIEF DESCRIPTIONS OF THE DRAWINGS

FIG. 1 is a cross-sectional view of a main part of a semiconductor device of an embodiment.

FIG. 2 is a cross-sectional view of a main part of a semiconductor device of an embodiment.

FIG. 3 is a cross-sectional view of a main part of a semiconductor device of an embodiment.

FIG. 4 is an explanatory diagram for explaining an energy band structure of a memory element in the semiconductor device of an embodiment.

FIG. 5 is a cross-sectional view of a main part during a manufacturing process of the semiconductor device of an embodiment.

FIG. 6 is a cross-sectional view of a main part during the manufacturing process of the semiconductor device following FIG. 5.

FIG. 7 is a cross-sectional view of a main part during the manufacturing process of the semiconductor device following FIG. 6.

FIG. 8 is a cross-sectional view of a main part during the manufacturing process of the semiconductor device following FIG. 7.

FIG. 9 is a cross-sectional view of a main part during the manufacturing process of the semiconductor device following FIG. 8.

FIG. 10 is a cross-sectional view of a main part during the manufacturing process of the semiconductor device following FIG. 9.

FIG. 11 is a cross-sectional view of a main part during the manufacturing process of the semiconductor device following FIG. 10.

FIG. 12 is a cross-sectional view of a main part during the manufacturing process of the semiconductor device following FIG. 11.

FIG. 13 is a cross-sectional view of a main part during the manufacturing process of the semiconductor device following FIG. 12.

FIG. 14 is a cross-sectional view of a main part during the manufacturing process of the semiconductor device following FIG. 13.

FIG. 15 is a cross-sectional view of a main part during the manufacturing process of the semiconductor device following FIG. 14.

FIG. 16 is a cross-sectional view of a main part during the manufacturing process of the semiconductor device following FIG. 15.

FIG. 17 is a cross-sectional view of a main part during the manufacturing process of the semiconductor device following FIG. 16.

FIG. 18 is a cross-sectional view of a main part during the manufacturing process of the semiconductor device following FIG. 17.

FIG. 19 is a cross-sectional view of a main part showing a memory element of a first study example.

FIG. 20 is an explanatory diagram showing an energy band structure of the memory element of the first study example.

FIG. 21 is a cross-sectional view of a main part showing a memory element of a second study example.

FIG. 22 is an explanatory diagram showing an energy band structure of the memory element of the second study example.

FIG. 23 is a cross-sectional view of a main part showing a memory element of a third study example.

FIG. 24 is an explanatory diagram showing an energy band structure of the memory element of the third study example.

FIG. 25 is a cross-sectional view of a main part of a semiconductor device of a modification example.

### DETAILED DESCRIPTION

The following embodiment will be, if necessary, for convenience, described by being divided into a plurality of embodiments or sections. However, unless otherwise stated, they are not unrelated to each other, and are in a relationship in which one is a variation, details, or a supplementary explanation of a part or all of the other one. In addition, in the following embodiment, when referring to the number of elements and the like (including number of pieces, numerical value, amount, range, etc.), unless otherwise stated or clearly limited to a specific number in principle, they are not limited to the specific number and may be more or less than the specific number. Furthermore, in the following embodiment, it goes without saying that, unless otherwise stated or clearly considered to be essential in principle, the components thereof (including component steps, etc.) are not necessarily essential. Similarly, in the following embodiment, when referring to the shapes, positional relationship and the like of the components, unless otherwise stated and clearly considered to be a different case in principle, components and the like the shape and the like of which are substantially similar or proximate to that of the embodiment are included. The same is true for the numerical value and range described above.

Hereinafter, descriptions of the embodiment will be made based on the drawings. Note that components having the same function are denoted by the same reference symbols throughout the drawings for describing the embodiments, and a repetitive description thereof is omitted. In the embodiment described below, unless particularly essential, descriptions of the same or similar parts will not be repeated in principle.

In the drawings referred in the embodiment, hatching may be omitted even in a cross-sectional view to facilitate understanding the drawing. In addition, hatching may be added even in a plan view to facilitate understanding the drawing.

### Embodiment

<About Structure of Semiconductor Device>

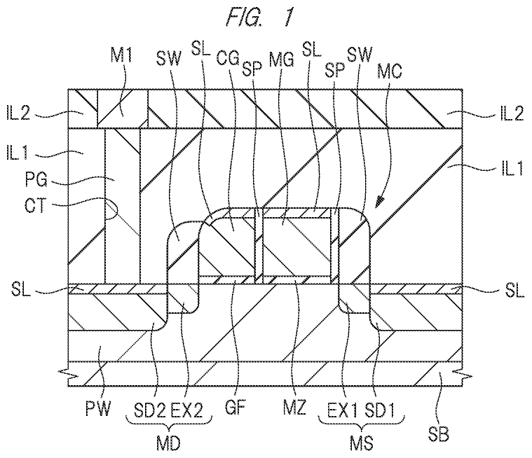

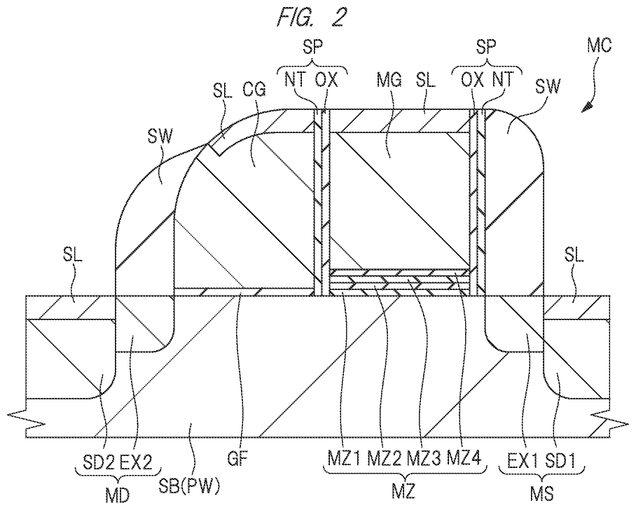

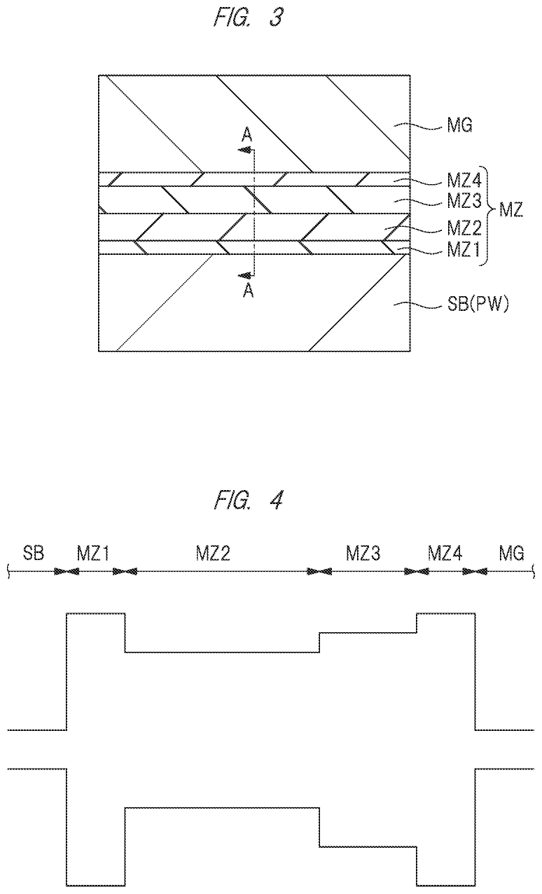

The semiconductor device of this embodiment will be described with reference to the accompanying drawings. FIGS. 1 to 3 are cross-sectional view of a main part of the semiconductor device of a present embodiment. FIG. 2 is a partially enlarged sectional view showing an enlarged portion of the semiconductor device of FIG. 1, FIG. 3 is a partially enlarged cross-sectional view showing a part of FIG. 2 further enlarged. FIG. 4 is an explanatory view showing an energy band structure of the memory element MC.

The semiconductor device of the present embodiment is a semiconductor device including a nonvolatile memory element, a flash memory, and a nonvolatile semiconductor memory device. FIG. 1 is a cross-sectional view of a main part of a memory element formation region which is a region in which a memory element MC forming a nonvolatile memory is formed. Note that FIGS. 1 and 2 show cross-sections perpendicular to the extending direction of a memory gate electrode MG and a control gate electrode CG forming the memory element MC (a direction perpendicular to the paper plane of FIGS. 1 and 2). In FIG. 3, from FIG. 2, a portion of semiconductor substrate SB and the gate electrode MG and an insulating film MZ interposed between them are shown in an enlarged manner. FIG. 4 shows an energy band structure at a location along the line A-A in FIG. 3. That is, FIG. 4 is an energy band diagram, in the memory element MC shown in FIGS. 1 to 3, energy at a position crossing the insulating film MZ sandwiched between the semiconductor substrate SB and the memory gate electrode MG in the thickness direction (the thickness direction of the insulating film MZ), the horizontal axis of FIG. 4 corresponds to the position in the thickness direction, the vertical axis of FIG. 4 corresponds to the energy.

As shown in FIGS. 1 and 2, to the semiconductor substrate SB, a memory element (storage element, memory cell) MC of the nonvolatile memory including a memory transistor and a control transistor is formed. Actually, a plurality of memory elements MC are formed in an array on the semiconductor substrate SB.

As shown in FIGS. 1 and 2, the memory element MC of the non-volatile memory is a split-gate memory element, and is obtained by connecting two MISFETs of a control transistor having a control gate electrode CG and a memory transistor having a memory gate electrode MG.

Here, a MISFET including a gate insulating film and a memory gate electrode MG including a charge accumulating portion is referred to as a memory transistor, and a MISFET including a gate insulating film and a control gate electrode CG is referred to as a control transistor. Since the control transistor is a memory cell selection transistor, it can also be regarded as a selection transistor.

Hereinafter, the configuration of the memory element MC will be described in detail.

As shown in FIGS. 1 to 3, the memory element MC of the nonvolatile memory has n-type semiconductor regions MS, MD for source and drain formed in a p-type well PW of the semiconductor substrate SB, a control gate electrode CG formed via an insulating film GF on the semiconductor substrate SB (p-type well PW), and the memory gate electrode MG formed via the insulating film MZ on the semiconductor substrate SB (p-type well PW). The insulating film GF is formed between the control gate electrode CG and the semiconductor substrate SB (p-type well PW). Further, the insulating film MZ is formed between the memory gate electrode MG and the semiconductor substrate SB (p-type well PW).

On both sides of the side walls of the memory gate electrode MG, a side wall insulating film SP is formed, and the control gate electrode CG and the memory gate electrode MG are adjacent to each other via the side wall insulating film SP. That is, between the control gate electrode CG and the memory gate electrode MG, the side wall insulating film SP is interposed.

Sidewall insulating film SP is formed of a stacked film of a silicon oxide film OX and a silicon nitride film NT. The silicon oxide film OX forming the side wail insulating film SP is adjacent to the memory gate electrode MG, and the silicon oxide film OX forming the side wall insulating film SP is interposed between the silicon nitride film NT constituting the side wall insulating film SP and the memory gate electrode MG.

The control gate electrode CG and the memory gate electrode MG, in a state interposing the side wall insulating film SP between their opposing side surfaces, extend along a main surface of the semiconductor substrate SB and arranged side by side. The control gate electrode CG and the memory gate electrode MG are formed via an insulating film GF or the insulating film MZ on the semiconductor substrate SB (p-type well PW) between the semiconductor region MD and the semiconductor region MS. The memory gate electrode MG is located on the semiconductor region MS side, and the control gate electrode CG is located on the semiconductor region MD side.

The insulating film GF formed between the control gate electrode CG and the semiconductor substrate SB (p-type well PW), i.e., the insulating film GF under the control gate electrode CG functions as a gate insulating film of the control transistor. The insulating film GF is formed of, for example, a silicon oxide film or a silicon oxynitride film.

The insulating film MZ formed between the memory gate electrode MG and the semiconductor substrate SB (p-type well PW), i.e., the insulating film MZ under the memory gate electrode MG functions as a gate insulating film of the memory transistor (gate insulating film having a charge accumulating portion therein). The insulating film MZ can be regarded as an insulating film having a charge accumulating portion therein (here, a insulating film MZ2).

The insulating film MZ is a stacked insulating film obtained by stacking a plurality of insulating films. Specifically, the insulating film MZ includes a stacked film of an insulating film MZ1, an insulating film MZ2 formed on the insulating film MZ1, an insulating film MZ3 formed on the insulating film MZ2, an insulating film MZ4 formed on the insulating film MZ3. The insulating film MZ1 is adjacent to the semiconductor substrate SB (p-type well PW), and the insulating film MZ4 is adjacent to the memory gate electrode MG.

Here, the insulating film MZ1 is preferably formed of a silicon oxide film or a silicon oxynitride film. The insulating film MZ2 is formed of a material (high dielectric constant material) containing hafnium (Hf) and oxygen (O), and is preferably formed of a hafnium oxide film (typically a HfO2 film) or a hafnium silicate film (HfxSi1-xO2 film). The insulating film MZ2 is in contact with the insulating film MZ1. The insulating film MZ3 is a polycrystalline film formed of a material (high dielectric constant material) that contains a metal (metal element) and oxygen (O) (as a constituent element), and is preferably formed of an aluminum oxide film (typically, a Al2O3 film), an aluminum oxynitride film (AlON film), or an aluminum silicate film (AlSiO film), and is particularly preferably formed of an aluminum oxide film. The insulating film MZ3 is in contact with the insulating film MZ2. The insulating film MZ4 is preferably formed of a silicon oxide film (oxide film) or a silicon oxynitride film (oxynitride film). The insulating film MZ4 is in contact with the insulating film MZ3. Further, the insulating film MZ4 is in contact with the gate electrode MG.

A thickness of the insulating film MZ1 may be, for example, about 2 to 5 nm. A thickness of the insulating film MZ2 may be, for example, about 2 to 5 nm. A thickness of the insulating film MZ3 may be, for example, about 2 to 10 nm. A thickness of the insulating film MZ4 may be, for example, about 1 to 6 nm.

In the insulating film MZ, the insulating film MZ2 is an insulating film having a charge storage function. That is, in the insulating film MZ, the insulating film MZ2 is an insulating film for accumulating charges, and functions as a charge accumulation layer (charge accumulating portion). That is, the insulating film MZ2 is a trapping insulating film formed in the insulating film MZ. Here, the trapping insulating film refers to an insulating film capable of accumulating charges. Thus, as an insulating film having a trapped level (charge storage layer), the insulating film MZ2 is used. Therefore, the insulating film MZ can be regarded as an insulating film having a charge accumulating portion therein (here, the insulating film MZ2).

In the insulating film MZ, the insulating film MZ3 and the insulating film MZ1 located above and below the insulating film MZ2 which is a trapping insulating film can function as a charge block layer (charge confinement layer) for confining charges in the trapping insulating film. In the insulating film MZ between the gate electrode MG and the semiconductor substrate SB (p-type well PW), the insulating film MZ2 is a trapping insulating film, by using a structure to sandwich the insulating film MZ2 between the insulating films MZ1, MZ3 which function as a charge block layer, the insulating film MZ2 can accumulate charges.

The insulating film MZ has a structure in which the charge accumulation layer (here, the insulating film MZ2) is sandwiched between the charge block layer (here, the insulating films MZ1, MZ3) so that it can function as a gate insulating film having the charge retaining function of the memory element MC, and, as compared with the potential barrier height of the charge accumulation layer (here, the insulating film MZ2), the potential barrier height of the charge block layer (here, the insulating film MZ1, MZ3) becomes higher. That is, each band gap of the insulating film MZ1 and the insulating film MZ3 is larger than the band gap of the insulating film MZ2 (see FIG. 4). This can be achieved by forming the insulating films MZ1, MZ2, MZ3 using the materials described above. That is, since the silicon oxide film, the silicon oxynitride film, the aluminum oxide film, the aluminum oxynitride film, and the aluminum silicate film have a band gap larger than that of the hafnium oxide film and the hafnium silicate film, they can be used as the charge blocking layer.

The insulating film MZ2 and the insulating film MZ3, respectively having higher dielectric constants than silicon oxide (relative dielectric constant), are insulating material film, so-called High-k film (high dielectric constant film, high dielectric constant insulating film). It should be noted that, in the present application, a High-k film, a high-conductivity film, a high-dielectric insulation film, a high-dielectric-gate insulating film, or a high-dielectric material means a film or material having a higher dielectric constant (specific dielectric constant) than silicone oxide. Each of the aluminum oxide film, the aluminum oxynitride film, the aluminum silicate film, the hafnium oxide film, and the hafnium silicate film is a high dielectric constant insulating film, and has a dielectric constant (relative dielectric constant) higher than that of silicon oxide. The high dielectric constant film is a film having a dielectric constant higher than that of silicon oxide as described above, but it is more preferable when the dielectric constant is higher than that of silicon nitride. When each of the insulating films MZ2, MZ3 is formed of the above-mentioned material, the dielectric constant of each of the insulating films MZ2, MZ3 is higher than the dielectric constant of the silicon nitride.

Note that, in order to facilitate viewing the drawings, FIG. 1 illustrates the insulating film MZ formed of a stacked film of the insulating films MZ1, MZ2, MZ3, MZ4 simply as insulating film MZ, in practice, as shown in FIGS. 2 and 3, the insulating film MZ is formed of a stacked film of insulating films MZ1, MZ2, MZ3, MZ4.

The control gate electrode CG is formed of a conductive film, for example, a silicon film such as an n-type polysilicon film (doped polysilicon film in which n-type impurities are introduced).

The memory gate electrode MG is formed of a conductive film, for example, a silicon film such as an n-type polysilicon film. The silicon film forming the memory gate electrode MG may be a doped polysilicon film in which n-type impurities are introduced, but other forms may be a doped polysilicon film in which p-type impurities are introduced, or a non-doped polysilicon film in which impurities are not intentionally introduced. Here, the memory gate electrode MG is formed of a patterned silicon film, and the control gate electrode CG is formed in a sidewall spacer shape via a sidewall insulating film SP on one side v/all of the memory gate electrode MG. Further, although the descriptions have been made about the case of using a silicon gate electrode to the memory gate electrode MG and the control gate electrode CG, as another form, it is also possible to use a metal gate electrode as one or both of the memory gate electrode MG and the control gate electrode CG.

Semiconductor region MS is formed on the semiconductor substrate SB at a position adjacent to the memory gate electrode MG and the gate length direction in plan view, and the semiconductor region MD is formed on the semiconductor substrate SB at a position adjacent to the control gate electrode CG in the gate length direction in plan view. On the side wail of the side not adjacent to the memory gate electrode MG in the control gate electrode CG, the sidewall spacer SW is formed as a sidewall insulating film. On the side wall of the side not adjacent to the control gate electrode CG in the memory gate electrode MG, the sidewall spacer SW is formed via the sidewall insulating film SP. Therefore, between the side wall spacer SW and the memory gate electrode MG, the side wall insulating film SP is interposed.

Semiconductor region MS is formed on the semiconductor substrate SB at a position adjacent to the memory gate electrode MG and the gate length direction in plan view, and the semiconductor region MD is formed on the semiconductor substrate SB at a position adjacent to the control gate electrode CG in the gate length direction in plan view. On the side wall of the side not adjacent to the memory gate electrode MG in the control gate electrode CG, the sidewall spacer SW is formed as a sidewall insulating film. On the side wall of the side not adjacent to the control gate electrode CG in the memory gate electrode MG, the sidewall spacer SW is formed via the sidewall insulating film SP. Therefore, between the side wall spacer SW and the memory gate electrode MG, the side wall insulating film SP is interposed.

The low-density n-type semiconductor region EX1 is formed below the sidewall spacer SW on the sidewall of the memory gate voltage MG so as to be adjacent to the channel region of the memory transistor, and the high-density n+ type semiconductor region SD1 is formed so as to be separated by n− type semiconductor region EX1 from the channel region of the memory transistor and so as to be adjacent to the low-density n+ type semiconductor region SD1. The low-density n− type semiconductor region EX2 is formed below the sidewall spacer SW on the sidewall of the control gateway CG so as to be adjacent to the channel region of the control transistor, and the high-density n+ type semiconductor region SD2 is formed to be adjacent to the low-density n+ type semiconductor region EX2 and so as to be separated by n− type semiconductor region EX2 from the channel region of the control transistor. The channel region of the memory transistor is formed under the insulating film MZ under the memory gate electrode MG, and the channel region of the control transistor is formed under the insulating film GF under the control gate electrode CG.

A metal silicide layers SL is formed on the n+ semiconductor regions SD1, SD2, the memory gate electrodes MG, and the control gate electrodes CG by the salicide (self aligned silicide) technique or the like. If unnecessary, the metal silicide layer SL may be omitted.

Next, a structure of an upper layer of the memory element MC will be described.

As shown in FIG. 1, on the semiconductor substrate SB, the insulating film IL1 is formed as an interlayer insulating film so as to cover the control gate electrode CG, the memory gate electrode MG and the sidewall spacer SW. An upper surface of the insulating film IL1 is planarized. A contact hole (through hole) CT is formed in the insulating film IL1, and a conductive plug PG is embedded as a connecting conductor portion in the contact hole CT.

The contact hole CT and the plug PG embedded therein are formed on the n+ type semiconductor region SD1, on the n+ type semiconductor region SD2, on the control gate element CG, and on the memory gate element MG and so forth.

A wiring M1 is formed on the insulating film IL1 in which the plug PG is embedded. The wiring M1 is, for example, damascene wiring (embedded wiring), and is embedded in a wiring groove provided in the insulating film IL2 formed on the insulating film IL1. The interconnection M1 is electrically connected to the n+ type semiconductor region SD1, the n+ type semiconductor region SD2, the control gate electrode CG, the memory gate electrode MG, or the like via the plug PG. Although more wiring and the insulating film of the upper layer are also formed, illustration and description thereof will be omitted here.

<Operation of Semiconductor Device>

Next, an operation example of the nonvolatile memory element MC will be described. In this embodiment, the injection of electrons into the charge storage portion (here, the insulating film MZ2) in the insulating film MZ of the memory transistor is defined as “programming”, and the injection of holes (hole: holes) is defined as “erasing”.

As a writing method, a writing method called SSI (source side injection) method can be used.

Upon programming of the SSI method, for example, in a selected memory cell, a positive voltage higher than an applied voltage of the semiconductor region MD is applied to the semiconductor region MS, a positive voltage is applied to the control gate electrode CG, and a positive voltage higher than the applied voltage of the control gate electrode CG is applied to the memory gate electrode MG. Programming is performed by injecting electrons into the charge storage layer (here, the insulating film MZ2) in the insulating film MZ of the selected memory cell. At this time, hot electrons are generated in the channel region (between the source and drain) under a part between the two gate electrodes (memory gate electrode MG and the control gate electrode CG), and the hot electrons are injected into the charge storage layer (here, the insulating film MZ2) in the insulating film MZ under the memory gate electrode MG. The injected hot electrons are trapped at a trapped level of the charge storage layer (here, the insulating film MZ2) in the insulating film MZ, resulting in an increase in the threshold voltage of the memory transistor. That is, the memory transistor is put in a programmed state.

As an erasing method, an erasing method in which erasing is performed by FN (Fowler-Nordheim) tunneling, which is so-called FN method, can be used.

In the erasing of the FN method, for example, in a selected memory cell, the semiconductor regions MS, MD and the control gate electrode CG are set to 0 V and a positive high voltage is applied to the memory gate electrode MG. In the selected memory cell, erasing is performed by injecting holes from the memory gate electrode MG into the charge storage layer (here, the insulating film MZ2) in the insulating film MZ by tunneling. At this time, the holes are injected into the insulating film MZ by tunneling the insulating films MZ4, MZ3 by the FN tunneling effect from the memory gate electrode MG and then trapped in the trap level of the charge accumulation layer in the insulating film MZ (here, the insulating film MZ2), and the threshold voltage of the memory transistor is lowered (erased state) as a result.

As an erasing method, there is also an erasing method called BTBT (band-to-band tunneling) method. In the erasing of BTBT method, erasing is performed by injecting holes generated by BTBT into the charge storage layer (here, the insulating film MZ2) in the insulating film MZ from the semiconductor substrate (SB) side.

At the time of reading, for example, in the selected memory cell, a positive voltage higher than the voltage of the semiconductor region MS is applied to the semiconductor region MD. Then, by setting the voltage applied to the memory gate electrode MG at the time of reading to a value between the threshold voltage of the memory transistor in the programmed state and the threshold voltage of the memory transistor in the erased state, it is possible to determine the programmed state and the erase state.

<Semiconductor Device Manufacturing Process>

Next, an example of a method of manufacturing a semiconductor device including the nonvolatile memory element MC shown in FIG. 1 will be described with reference to FIGS. 5 to 18. FIGS. 5 to 18 are cross-sectional views of main parts during the manufacturing process of the semiconductor device according to the present embodiment.

As shown in FIG. 5, first, a semiconductor substrate (semiconductor wafer) SB formed of, for example, p-type single crystal silicon having a specific resistance of about 1 to 10 Ωcm is prepared. Then, a device isolation region (not shown) defining the active regions is formed on the main surface of the semiconductor substrate SB by the STI (shallow trench isolation) method or the like.

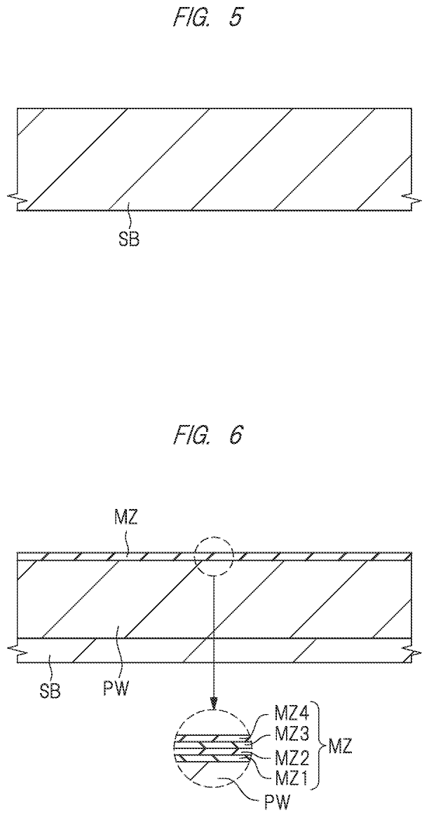

Next, as shown in FIG. 6, a p-type well PW is formed in the semiconductor substrate SB in a memory cell formation region by ion implantation or the like. The p-type well PW2 is formed to a predetermined depth from the main surface of the semiconductor substrate SB.

Next, after the surface of the semiconductor substrate SB (p-type well PW) is cleaned by dilute hydrofluoric acid cleaning or the like, an insulating film MZ is formed on the main surface (surface of the p-type well PW) of the semiconductor substrate SB. The insulating film MZ if formed of a stacked film (stacked insulating film) of an insulating film MZ1, an insulating film MZ2 formed on the insulating film MZ1, an insulating film MZ3 formed on the insulating film MZ2, and an insulating film MZ4 formed on the insulating film MZ3.

Note that, to make the illustration easier to view, in FIG. 6, the insulation film MZ formed of the insulation film MZ1, the insulation film MZ2, the insulation film MZ3 and the insulation film MZ4 are simply illustrated as the insulation film MZ. In practice, the insulation film MZ is formed of a stacked film of the insulation film MZ1, the insulation film MZ2, the insulating film MZ3, and the insulation film MZ4, as shown in the enlarged view of the area enclosed by the dotted circle in FIG. 6.

A process of forming the insulating film MZ can be performed as follows.

First, on the surface of the semiconductor substrate SB, i.e., on the surface of the p-type well PW, the insulating film MZ1 is formed.

The insulating film MZ1 is formed of a silicon oxide film and can be formed by thermal oxidation treatment. As another embodiment, after a silicon oxide film (insulating film MZ1) is formed by thermal oxidation, a thermal nitridation treatment or a plasma-nitridation treatment is performed, so that the silicon oxide film (insulating film MZ1) can be nitrided and nitrogen can be introduced. In that case, the insulating film MZ1 becomes a silicon oxynitride film.

Then, the insulating film MZ2 is formed on the insulating film MZ1. The insulating film MZ2 is formed of a material (high dielectric constant material) containing hafnium (Hf) and oxygen (O), and is preferably formed of a hafnium oxide film or a hafnium silicate film, and can be formed using, for example, a CVD (chemical vapor deposition) method or an ALD (atomic layer deposition) method.

Then, the insulating film MZ3 is formed on the insulating film MZ2. The insulating film MZ3 is formed of a material (high dielectric constant material) containing a metal (metal element) and oxygen (O), preferably an aluminum oxide film, an aluminum oxynitride film, or an aluminum silicate film, particularly preferably an aluminum oxide film, and can be formed by, for example, a CVD method or an ALD method.

Then, the insulating film MZ4 is formed on the insulating film MZ3. The insulating film MZ4 is formed of a silicon oxide film or a silicon oxynitride film, and can be formed by, for example, a CVD method or an ALD method.

In this way, on the semiconductor substrate SB (p-type well PW), the insulating film MZ that is a stacked insulating film in which the insulating films MZ1, MZ2, MZ3, MZ4 are stacked in this order from the bottom is formed.

Next, a heat treatment (annealing) can be performed. By this heat treatment, the insulating film MZ3 forming the insulating film MZ can be crystallized, and the insulating film MZ3 can be a polycrystalline film. Further, by this heat treatment, not only the insulating film MZ3, the insulating film MZ2 may be also crystallized.

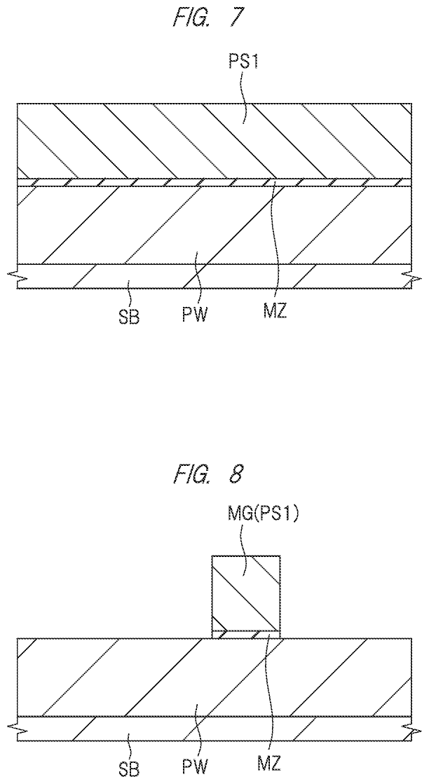

Next, as shown in FIG. 7, on the main surface of the semiconductor substrate SB (main surface entire), i.e., on the insulating film MZ, as a conductive film for forming the gate electrode MG, a silicon film PS1 is formed. The silicon film PS1 is formed of a polycrystalline silicon film, and can be formed by a CVD method or the like. However, at the time of film formation, after the silicon film PS1 is formed as an amorphous silicon film, the amorphous silicon film can be formed as a polycrystalline silicon film by subsequent heat treatment. When an n-type or p-type impurity is introduced into the silicon film PS1, an n-type or p-type impurity can be introduced at the time of film formation on the silicon film PS1 or after film formation.

Next, as shown in FIG. 8, the silicon film PS is patterned using photolithography and an etching technique to form a memory gate electrode MG formed of a patterned silicon film PS1. In the area for forming the memory cell, the insulating film MG other than the portion covered with the memory gate electrode MG may be removed by performing dry etching or wet etching after the dry etching performed in the patterning step of the silicon film PS1. The insulating film MZ under the memory gate electrode MG remains without being etched, and becomes a gate insulator of the memory transistor (gate insulator having a charge accumulating portion). In this manner, the memory gate electrode MG is formed via the insulating film MZ on the semiconductor substrate SB (p-type well PW).

Further, as another embodiment, after forming an insulating film such as a silicon oxide film on the silicon film PS, by patterning the stacked film between the silicon film PS and the insulating film thereon, it is also possible to form a memory gate electrode MG. In this case, on the memory gate electrode MG, a state in which a cap insulating film having the same planar shape as the memory gate electrode MG is formed.

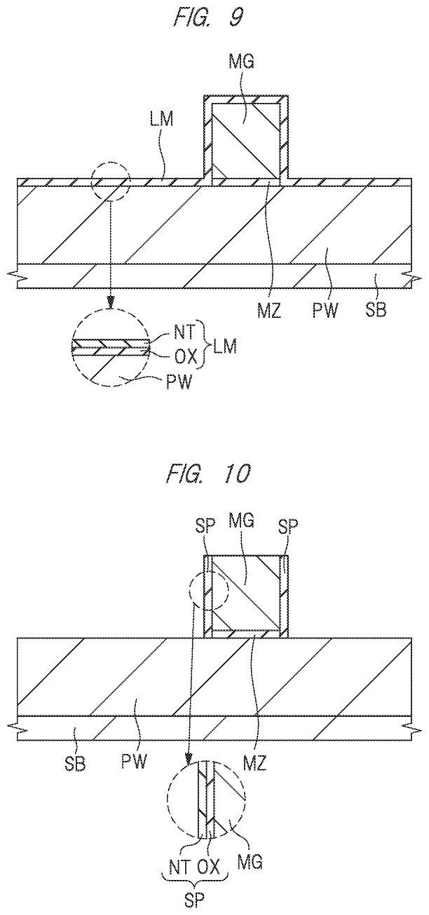

Next, as shown in FIG. 9, on the semiconductor substrate SB (p-type well PW), so as to cover the memory gate electrode MG, a stacked film LM formed of the silicon nitride film NT on the silicon oxide film OX and the silicon oxide film OX is formed. Each of the silicon oxide film OX and the silicon nitride film NT can be formed by a CVD method or the like. Note that, in order to facilitate viewing of the drawings, in FIG. 9, the stacked film LM of the silicon oxide film OX and the silicon nitride film NT is illustrated as a mere film. However, in practice, as shown in an enlarged view of a region surrounded by a dotted circle in FIG. 9, the stacked film LM is a stacked film of the silicon oxide film OX and the silicon nitride film NT.

Next, as shown in FIG. 10, by etching back the stacked film LM of the silicon oxide film OX and the silicon nitride film NT, remaining the stacked film LM on both side wails of the memory gate electrode MG as sidewall insulating film SP, the other part of the stacked film LM is removed. As shown in an enlarged view of a region surrounded by a dotted circle in FIG. 10, the sidewall insulating film SP is composed of a stacked film of a silicon oxide film OX on the side wall of the memory gate electrode MG and the silicon nitride film NT on the silicon oxide film OX.

Next, by performing a cleaning process, after cleaning the main surface of the semiconductor substrate SB, as shown in FIG. 11, the main surface (surface) of the semiconductor substrate SB (p-type well PW), an insulating film GF for the gate insulating film of the control transistor is formed. The insulating film GF is formed of a silicon oxide film and can be formed by, for example, a thermal oxidation method. Further, when the cap insulating film is not formed on the memory gate electrode MG, an insulating film ZM of the same kind as the insulating film GF can be formed to the upper surface of the memory gate electrode MG.

Next, as shown in FIG. 11, on the main surface of the semiconductor substrate SB (entire main surface), i.e. on the insulating film GF, so as to cover the memory gate electrode MG and the sidewall insulating film SP, a silicon film PS2 as a conductor film for forming the control gate electrode CG is formed. Silicon film PS2 is formed of polycrystalline silicon film, and it can be formed by using a CVD method or the like. At the time of film formation, after forming the silicon film PS2 as an amorphous silicon film, the amorphous silicon film can also be a polycrystalline silicon film in a subsequent heat treatment. In addition, when an n-type or p-type impurity is introduced into the silicon film PS2, an n-type or p-type impurity can be introduced at the time of film formation on the silicon film PS2 or after film formation.

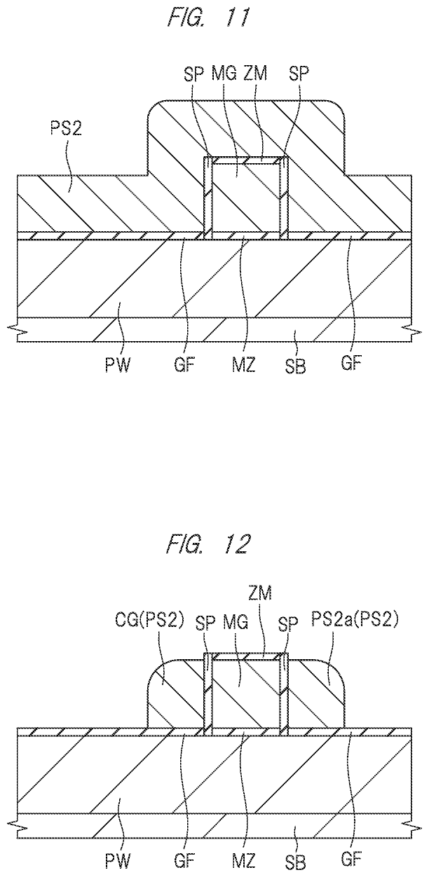

The silicon film PS2 is then etched back by an anisotropic etch technique. By this etchback process, the silicon film PS2 is left in a sidewall spacer shape via the sidewall insulating film SP on both sidewalls of the memory gate electrode MG, and the silicon film PS2 of the other regions is removed. Thus, as shown in FIG. 12, among both of the side walls of the memory gate electrode MG, the silicon film PS2 remaining in the sidewall spacer shape via the sidewall insulating film SP on one of the side walls forms the control gate electrode CG, and also, a silicon spacer PS2a is formed by the silicon film PS2 remaining in the sidewall spacer shape via the sidewall insulating film SP on the other side wall. The control gate electrode CG is formed so as to be adjacent to the memory gate electrode MG via the side wall insulating film SP.

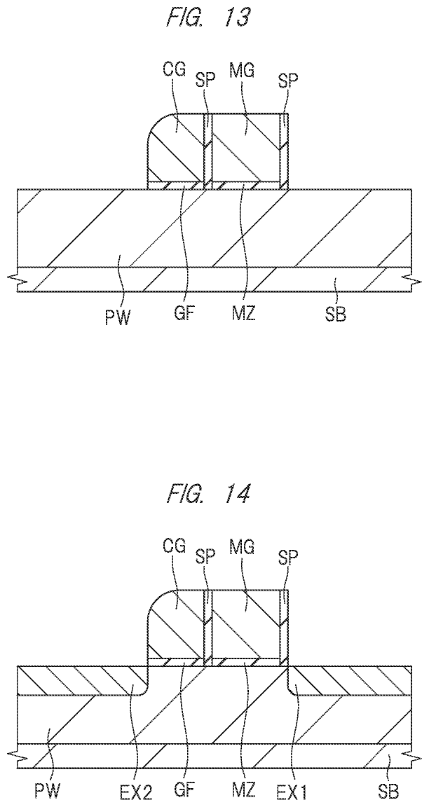

Next, as shown in FIG. 13, a photolithography technique and an etching technique are used to remove the silicon spacer PS2a and the control gate electrode CG remains without etching. Thereafter, among the insulating film GF, the portion exposed without being covered by the control gate electrode CG is removed by etching (e.g., wet etching). At this time, the insulating film ZM on the memory gate electrode MG can also be removed. The insulating film GF under the control gate electrode CG remains without being removed, and becomes a gate insulating film of the control transistor.

Next, an n-type impurity is introduced into the semiconductor substrate SB (p-type well PW) by using the control gate electrode CG and the memory gate electrode MG as masks (ion implantation blocking masks) by an ion implantation method or the like, whereby n− type semiconductor regions (impurity diffused layer) EX1, EX2 are formed as shown in FIG. 14.

Next, on the main surface of the semiconductor substrate SB, a sidewall spacer SW is formed so as to cover the control gate electrode CG, the memory gate electrode MG and the sidewall insulating film SP, after forming an insulating film (e.g., silicon oxide film), by etching back the insulating film, as shown in FIG. 15.

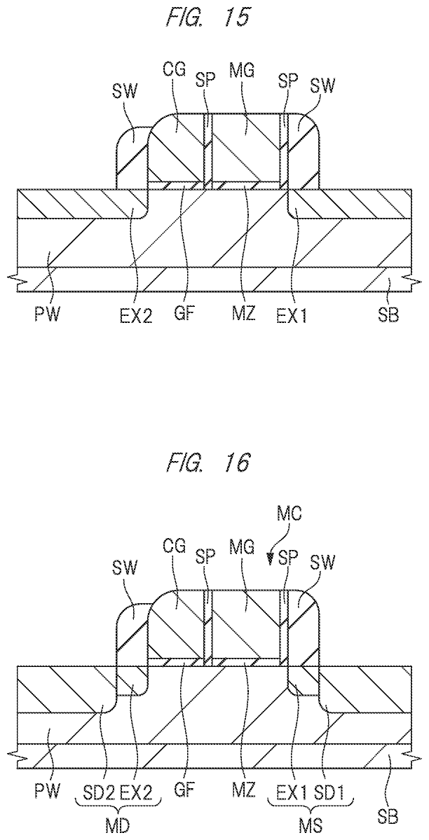

Next, as shown in FIG. 16, to form n+ type semiconductor regions SD1, SD2, an n-type impurity is introduced to the semiconductor substrate SB (p-type well PW) using an ion implantation method or the like, with the control gate electrode CG, the memory gate electrode MG and the sidewall spacer SW on their sidewalls being used as masks (ion implantation blocking masks).

Thus, the n-type semiconductor region MS that functions as a source region of the memory transistors is formed of the n− type semiconductor region EX1 and the n+ type semiconductor region SD1 having a higher charge density than the n− type semiconductor region EX1. By the n− type semiconductor region EX2 and the n+ type semiconductor region SD2 having a higher charge density than the n− type semiconductor region EX2, the n-type semiconductor region MD functioning as a drain region of the control transistors is formed.

Next, an activation annealing which is a heat treatment for activating impurities introduced beforehand is performed.

In this manner, the memory element MC of the nonvolatile memory is formed.

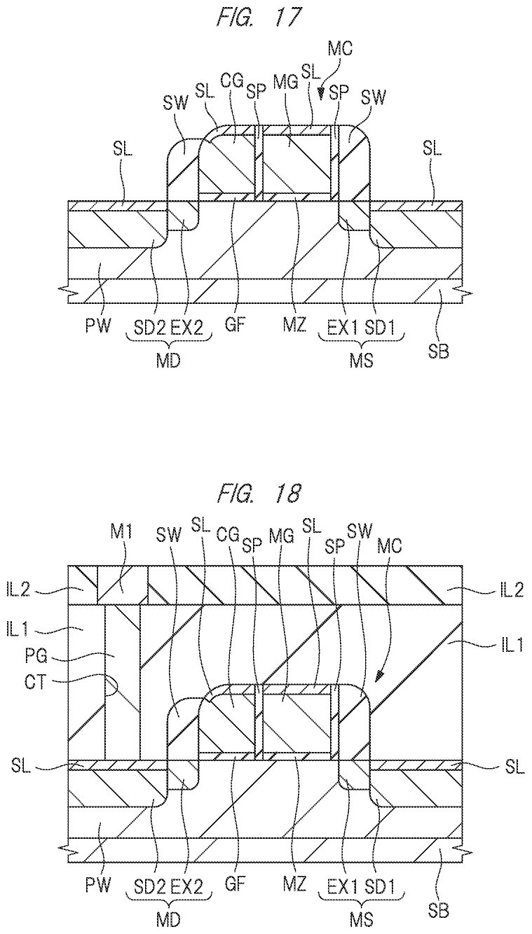

Next, as shown in FIG. 17, a metal silicide layer SL is formed by using a salicide technique. The metal silicide layer SL may be formed on the n+ semiconductor regions SD1, SD2, the control gate electrode CG, and the memory gate electrode MG.

Next, as shown in FIG. 18, on the entire main surface of the semiconductor substrate SB, so as to cover the control gate electrode CG, the memory gate electrode MG and the sidewall spacer SW, an insulating film IL1 is formed as an interlayer insulating film. After the insulating film IL1 is formed, the upper surface of the insulating film IL1 is planarized by a CMP (chemical mechanical polishing) method or the like as required. Then, after forming a contact hole CT on the insulating film IL1, a conductive plug PG is formed in the contact hole CT. Then, after forming an insulating film IL2 on the insulating film IL1 in which the plug PG is embedded, and after forming a wiring groove in the insulating film IL2, a wiring M1 is formed in the wiring groove using a single damascene technique. Thereafter, a second layer and subsequent wiring by a dual damascene method or the like will be formed but illustration and description thereof will be omitted here.

As described above, the semiconductor device of the present embodiment is manufactured.

<Major Features and Effects>

One of the main features of the present embodiment is that the gate insulating film for the memory element includes an insulating film MZ1 (first insulating film), an insulating film MZ2 thereon (second insulating film), an insulating film MZ3 thereon (third insulating film), and an insulating film MZ4 thereon (fourth insulating film). Here, the insulating film MZ2 (second insulating film) is a charge storage film formed of a high dielectric constant material containing hafnium and oxygen (insulating film having a charge accumulation function), and each band gap of the insulating film MZ1 (first insulating film) and the insulating film MZ3 (third insulating film) is larger than the band gap of the insulating film MZ2 (second insulating film). The third insulating film MZ3 is formed of a high dielectric constant material containing a metallic element and oxygen. The insulating film MZ4 (fourth insulating film) is a silicon oxide film or a silicon oxynitride film, and is adjacent to the memory gate electrode MG.

Meanwhile, as the gate insulating film for the memory element, ONO (oxide-nitride-oxide) film in which a silicon oxide film, a silicon nitride film and a silicon oxide film are stacked has been known. However, as the gate insulating film for the memory element, when using the ONO film, since the dielectric constant is relatively low, an EOT (equivalent oxide film thickness) of the gate insulating film becomes large. Therefore, there is a concern that the operating voltage is increased by increasing the EOT of the gate insulating film. Further, when trying to reduce the physical film thickness in order to reduce the EOT of the gate insulating film, there is a concern that degradation of the retention characteristics (charge retention characteristics, data retention characteristics) due to leakage occurs. These factors degrade the performance of the semiconductor device.

Therefore, in the present embodiment, a high dielectric constant film is used as the insulating film MZ2 functioning as a charge accumulation film and as the insulating film MZ3 functioning as an upper charge block film among the upper and lower charge block films sandwiching the charge accumulation film.

When a high dielectric constant film is used as the insulating film MZ3 that is a charge block film on the upper side, it is possible to increase the physical film thickness of the insulating film MZ3 while suppressing the EOT of the insulating film MZ2. Thus, charges accumulated in the charge storage film (here the insulating film MZ2) can be suppressed from escaping through the insulating film MZ3 unintentionally the memory gate electrode MG, so that it is possible to improve the retention properties of the memory device. Further, since the EOT can be reduced while ensuring the physical film thickness of the insulating film MZ3, it is possible to reduce the operating voltage of the memory device and improve the operation speed.

Further, if using a high dielectric constant film as the insulating film MZ2 that is a charge accumulation film, it is possible to increase the physical film thickness of the insulating film MZ2 while suppressing the EOT of the insulating film MZ2, and thus it is possible to improve the retention properties of the memory elements. The reason is that, when the insulating film MZ2 is thicker, a position at which charges are trapped can be farther from the surface of the insulating film MZ2 in the insulating film MZ2. Thus, it becomes difficult for the charges to escape from the insulating film MZ2, and the retention property of the memory device is improved.

When a high dielectric constant film is applied to a charge storage film (here, an insulating film MZ2), an insulating film formed of a material containing hafnium (Hf) and oxygen (O) (as a constituent element) can be suitably used, and a hafnium oxide film or a hafnium silicate film is particularly preferably used.

When using a high dielectric constant film as the upper charge block film (here insulating film MZ3), it is required to use a high dielectric constant film having a band gap larger than the band gap of the charge storage film (here insulating film MZ2). As the high dielectric constant film for the upper charge-blocking film (here, the insulating film MZ3), an insulating film formed of a material that contains a metal and oxygen (O) (as a constituent element) can be suitably used. However, an aluminum oxide film, an aluminum oxynitride film, or an aluminum silicate film is preferably used, and an aluminum oxide film is particularly preferably used. The reason is that the aluminum oxide film, the aluminum oxynitride film, and the aluminum silicate film are particularly suitable for the charge blocking film because the aluminum oxide film has a high insulating property because of its favorable film quality and has a large band gap.

In this embodiment, an insulating film MZ4 is formed on the insulating film MZ3, and the insulating film MZ4 is adjacent to the memory gate electrode MG. As a result, the retention characteristic of the memory element can be further improved. This will be described in detail below.

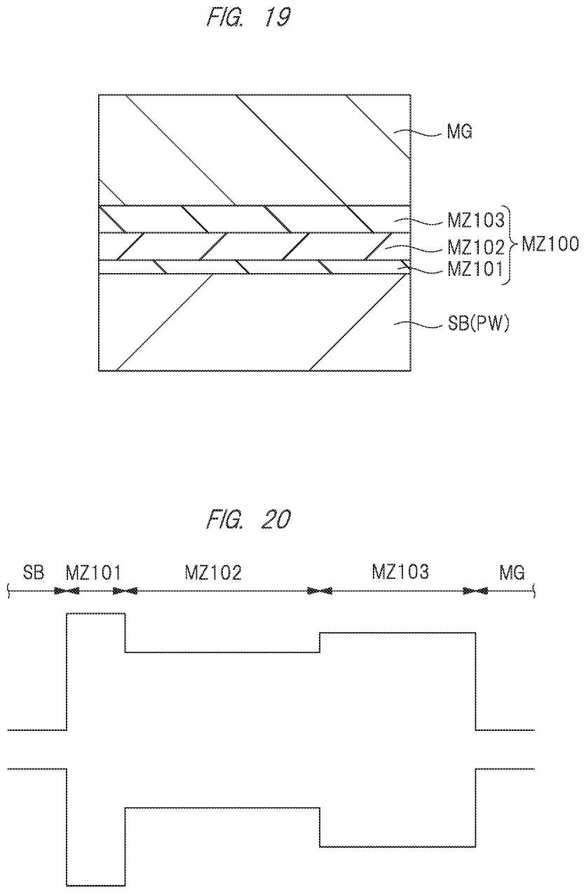

FIG. 19 is a cross-sectional view of a main part illustrating a memory element of a first study example studied by the inventors of the present invention, and FIG. 20 is an explanatory view illustrating an energy band structure of a memory element of a first study example, and they correspond to FIGS. 3 and 4, respectively.

In the case of the first study example of FIGS. 19 and 20, a gate insulating film MZ100 for a memory transistor is a stacked film formed of three layers including an insulating film MZ101 formed of the same material as the insulating film MZ1, an insulating film MZ102 formed of the same material as the insulating film MZ2, formed of an insulating film MZ103 formed of the same material as the insulating film MZ3. In the first study example, unlike the present embodiment, there is nothing corresponding to the insulating film MZ4, and the insulating film MZ103 corresponding to the insulating film MZ3 is adjacent to the memory gate electrode MG.

In the case of the first study example (FIGS. 19 and 20), there is such a concern that passing of the charges (here, electrons) to the memory gate electrode MG through the insulating film MZ3 that is an upper charge block film from the insulating film MZ2 that is a charge accumulation film may occur. Because the insulating film MZ103 is formed of a material as described above forming the insulating film ZM3, it tends to become a polycrystalline film crystallized by heat treatment or the like, since and grain boundaries of the polycrystalline film (grain boundaries) are a collection of defects that may be the leakage pass easily, charges can pass from the insulating film MZ102 to the memory gate electrode MG through the grain boundaries in the insulating film MZ103. Escape of charges through the insulating film MZ3 from the insulating film MZ2 that is a charge storage film charges to the memory gate electrode MG, may cause a variation of the threshold voltage of the memory transistor, it leads to a decrease in the retention properties of the memory element.

In addition, since the insulating film MZ103 is formed of the above-described materials forming the insulating film MZ3, it has the capability of trapping charges, although not as much as the insulating film MZ102 which is a charge storage film. That is, the insulating film MZ103, as compared with the silicon oxide film or silicon oxynitride film, the capability of trapping charges is increased. Then, since the insulating film MZ103 is adjacent to the memory gate electrode MG, charges trapped in the insulating film MZ103 is easily moved to the memory gate electrode MG. Since moving of the charges trapped in the insulating film MZ103 to the memory gate electrode MG may cause a variation of the threshold voltage of the memory transistor, it leads to a decrease in the retention properties of the memory element.

Therefore, in the case of the first study example (FIGS. 19 and 20), since the charges are easily removed through the grain boundaries of the insulating film MZ3 to the memory gate electrode MG from the insulating film MZ2 that is a charge accumulation film, and the charges trapped in the insulating film MZ3 are easily moved to the memory gate electrode MG neighboring the insulating film MZ3, the retention property of the memory element is lowered.

In contrast, in the present embodiment, an insulating film MZ4 formed of a silicon oxide film or silicon oxynitride film is formed on the insulating film MZ3, and the insulating film MZ4 is adjacent to the memory gate electrode MG (see FIGS. 2 and 3). Thus, it is possible to prevent the insulating film MZ3 from being in contact with the memory gate electrode MG since the insulating film MZ4 will be interposed between the insulating film MZ3 and the memory gate electrode MG. Therefore, in the present embodiment, ever, when the insulating film MZ3 has become a polycrystalline film, connection of the insulating film MZ2 that is a charge storage film and the memory gate electrode MG through the grain boundaries of the insulating film MZ3 can be prevented by the presence of the insulating film MZ4. Since it is possible to prevent the charges from escaping through the grain boundaries of the insulating film MZ3 to the memory gate electrode MG from the insulating film MZ2 that is a charge storage film by the presence of the insulating film MZ4 between the insulating film MZ3 and the memory gate electrode MG, it is possible to improve the retention properties of the memory element. Further, since the charges trapped in the insulating film MZ3 can be suppressed or prevented from moving to the memory gate electrode MG as the insulating film MZ4 is present between the insulating film MZ3 and the memory gate electrode MG, it is possible to improve the retention properties of the memory element. That is, as compared with the case of the first study example (FIGS. 39 and 20), in the case of the present embodiment (FIGS. 1 to 4), since it is possible to more accurately suppress or prevent removal of the charges are removed from the insulating film MZ2 that is a charge storage film through the grain boundaries of the insulating film MZ3 to the memory gate electrode MG, and moving of the charges trapped in the insulating film MZ3 to the memory gate electrode MG, it is possible to improve the retention property of the memory element. Therefore, it is possible to improve the performance of the semiconductor device having a memory element.

The insulating film MZ4 is a silicon oxide film or a silicon oxynitride film, but the silicon oxide film or the silicon oxynitride film has a low capability of trapping charges. That is, as compared with the insulating film MZ103 formed of the same material as the insulating film MZ3, the insulating film MZ4 formed of silicon oxide film or silicon oxynitride film has lower capability of trapping charges. Since the insulating film MZ4 is adjoined to the memory gate electrode MG, when the charges are trapped in the insulating film MZ4, the charges tend to move to the memory gate electrode MG. But since the insulating film MZ4 has a low capability to trap the charges, the amount (number) of charges trapped in the insulating film MZ4 themselves is small, and also the probability that the charge is trapped in the insulating film MZ4 is low. Therefore, the phenomena in which the charges trapped in the insulating film MZ4 move to the memory gate electrode MG neighboring the insulating film MZ4 is less likely to occur. In the present embodiment, rather than the insulating film MZ3, by the insulating film MZ4 formed of a silicon oxide film or a silicon oxynitride film and adjacent to the memory gate electrode MG, it is possible to accurately suppress or prevent the phenomenon of moving of the charges trapped in the charge block film (insulating films MZ3, MZ4) interposed between the charge storage film (insulating film MZ2) and the memory gate electrode MG to the memory gate electrode MG. Therefore, retention characteristics of the memory element can be improved. Therefore, it is possible to improve the performance of the semiconductor device having a memory element.

The insulating film MZ4 is preferably an amorphous film (i.e., an amorphous film) without being crystallized. Since the insulating film MZ4 is an amorphous film, it is possible to prevent occurring of the phenomena that charges trapped in the insulating film MZ3 move to the memory gate electrode MG through the grain boundaries of the insulating film MZ4. As a result, the retention characteristic of the memory element can be improved. Further, although the insulating film MZ4 is a silicon oxide film or silicon oxynitride film, silicon oxide or silicon oxynitride is difficult to be polycrystallized as compared with the material described above forming the insulating film MZ3. Therefore, by using a silicon oxide film or a silicon oxynitride film as the insulating film MZ4, the insulating film MZ4 can be easily formed as an amorphous film. In the present embodiment, by forming the insulating film MZ4 as a silicon oxide film or a silicon oxynitride film, in the gate insulating film of the memory transistor, a film (here, an insulating film MZ4) adjacent to the memory gate electrode MG can be a film that is difficult to trap charges and can be formed as a film in an amorphous state. Thus, it is easy to suppress the charge from moving from the gate insulating film of the memory transistor to the memory gate electrode MG. Therefore, retention characteristics of the memory element can be improved, and performance of the semiconductor device including the memory element, can be improved.

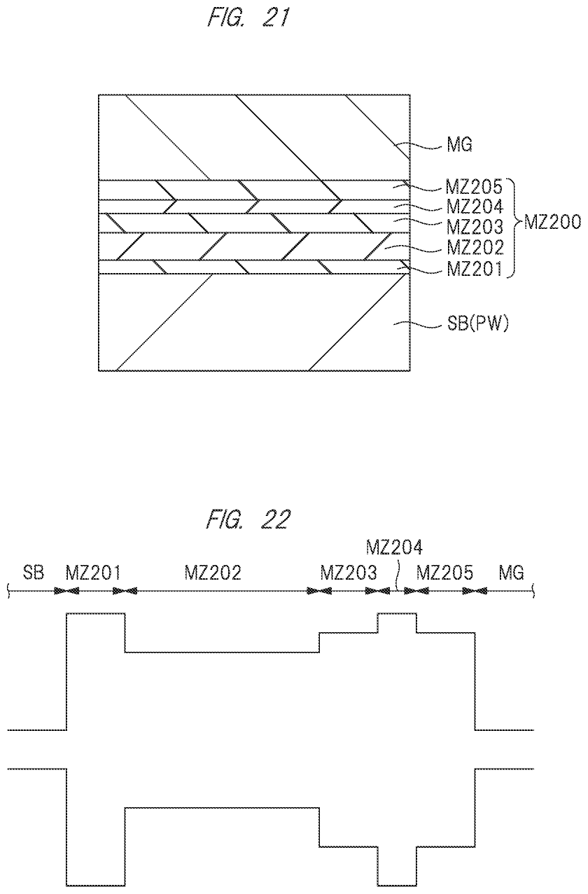

FIG. 21 is a cross-sectional view of a main part illustrating a memory element of a second study example studied by the inventors of the present invention, and FIG. 22 is an explanatory view illustrating an energy band structure of a memory element of a second study example, and they correspond to FIGS. 3 and 4, respectively.

For the second study example of FIGS. 21 and 22, a gate insulator MZ200 for a memory transistor is formed of a stacked film formed of five layers including an insulating film MZ201 formed of the same material as the insulating film MZ2, an insulating film MZ202 formed of the same material as the insulating film MZ3, an insulating film MZ203 formed of the same material as the insulating film MZ3, and an insulating film MZ204 formed of the same material as the insulating film MZ4, and an insulating film MZ205 formed of the same material as the insulating film MZ3. In the case of the second study example, unlike the present embodiment, the insulating film MZ204 corresponding to the insulating film MZ4 is not adjacent to the memory gate electrode MG, and the insulating film MZ205 formed of the same material as the insulating film MZ3 is interposed between the insulating film MZ204 and the memory gate electrode MG.

In the case of the second examination example (FIGS. 21 and 22), it is possible to prevent charges that have been trapped in the insulating film MZ203 from escaping through grain boundaries of the insulating film MZ204 to the memory gate electrode MG from the insulating film MZ202 that is a charge storage film, and to prevent charges that have been trapped in the insulating film MZ203 from moving to the memory gate electrode MG in accordance with the presence of the insulating film MZ204 formed on the insulating film MZ203.

However, in the case of the second study example (FIGS. 21 and 22), on the insulating film MZ204, an insulating film MZ205 formed of the same material as the insulating film MZ3 is formed, and the insulating film MZ205 is adjacent to the memory gate electrode MG. The insulating film MZ205 formed of materials similar to those of the insulating film MZ3 also has a capability of trapping charges, although not as much as the insulating film MZ202 which is a charge storage film. That is, the insulating films MZ203, MZ205 formed of the same materials as those of the insulating film MZ3 has a higher capability of trapping charges than the silicon oxide film or the silicon oxynitride film. Therefore, in the case of the second examination example (FIGS. 21 and 22), since the insulating film MZ205 is adjacent to the memory gate electrode MG, charges trapped in the insulating film MZ205 are easily moved to the memory gate electrode MG. Since moving of the charges trapped in the insulating film MZ205 to the memory gate electrode MG cause the variation of the threshold voltage of the memory transistor, it leads to a decrease in the retention properties of the memory element. Therefore, in the case of the second study example (FIGS. 21 and 22), since the charges trapped in the insulating film MZ205 are easily moved to the memory gate electrode MG neighboring the insulating film MZ205, the retention property of the memory element is lowered.

In contrast, in the present embodiment (FIGS. 1 to 4), an insulating film MZ4 formed of a silicon oxide film or a silicon oxynitride film is adjacent to the memory gate electrode MG. That is, in the gate insulator film of the memory transistor (insulating film MZ), which is adjacent to the memory gate electrode MG is an insulating film MZ4, and since the insulating film MZ4 is formed of a silicon oxide film or silicon oxynitride film, the capability of trapping charges is low. In the present embodiment, rather than the insulating film MZ103 or insulating film MZ105 formed of a material a3 described above, the insulating film MZ4 formed of silicon oxide film or silicon oxynitride film is adjacent to the memory gate electrode MG. Thus, as compared with the first study example and the second study example, in the present embodiment, it is possible to more accurately suppress or prevent such a phenomenon that the charges trapped in the charge block film interposed between the charge storage film (insulating film MZ2, MZ102, MZ202) and the memory gate electrode MG are moved to the memory gate electrode MG. Thus, in the present embodiment, in the gate insulating film of the memory transistor, the film adjacent to the memory gate electrode MG is formed of an insulating film MZ4 formed of a silicon oxide film or a silicon oxynitride film that is difficult to trap charges, thereby improving the retention property of the memory element. Therefore, it is possible to improve the performance of the semiconductor device having a memory element.

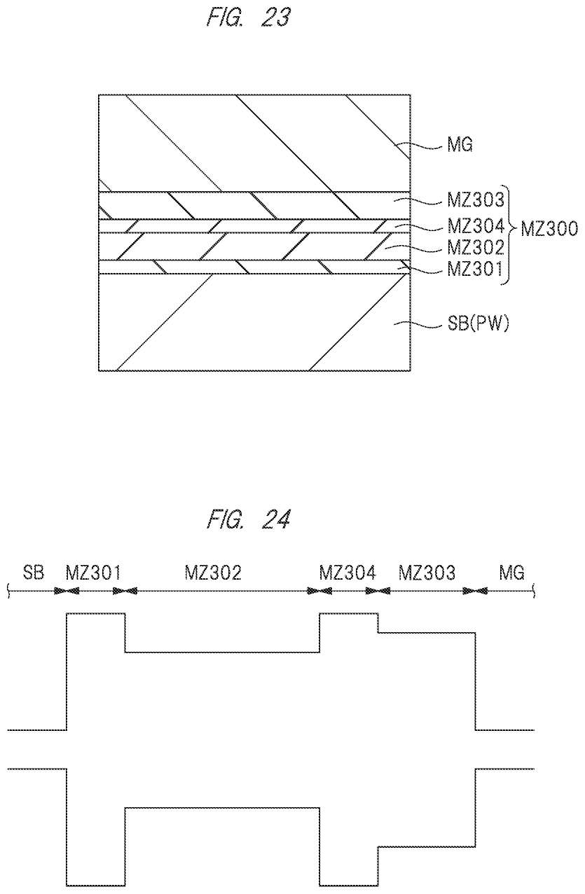

FIG. 23 is a cross-sectional view of a main part illustrating a memory element of a third study example studied by the inventors of the present invention, and FIG. 24 is an explanatory view illustrating an energy band structure of a memory element of a third study example, and they correspond to FIGS. 3 and 4, respectively.

In the case of the third study example of FIGS. 23 and 24, the gate insulating film MZ300 for a memory transistor is formed of a stacked film formed of four layers of an insulating film MZ301 formed of the same material as the insulating film MZ1, an insulating film MZ302 formed of the same material as the insulating film MZ2, an insulating film MZ303 formed of the same material as the insulating film MZ3, and an insulating film MZ304 formed of the same material as the insulating film MZ4. In the third study example, unlike the present embodiment, the insulating film MZ304 corresponding to the insulating film MZ4 (silicon oxide film or silicon oxynitride film) is not adjacent to the memory gate electrode MG, the insulating film MZ303 corresponding to the insulating film MZ3 is adjacent to the memory gate electrode MG, and the insulating film MZ304 is formed between the insulating film MZ303 and the insulating film MZ302.

In the case of the third study example (FIGS. 23 and 24), similarly to the first study example (FIGS. 19 and 20), the insulating film MZ303 formed of the same material as the insulating film MZ3 is adjacent to the memory gate electrode MG, the insulating film MZ303 has a capability of trapping charges although not as much as the insulating film MZ302 that is a charge accumulation film. Therefore, in the third study example (FIGS. 23 and 24), since the charges trapped in the insulating film MZ303 easily move to the memory gate electrode MG neighboring the insulating film MZ303, the retention property of the memory element is lowered.

In contrast, in the present embodiment, rather than the insulating film MZ3, the insulating film MZ4 formed of silicon oxide film or silicon oxynitride film is adjacent to the memory gate electrode MG. Thus, as compared with the first study example, the second study example, and the third study example, an the present embodiment, it is possible to more accurately suppress or prevent such a phenomenon that the charges trapped in the charge block, film interposed between the charge storage film (insulating film MZ2, MZ102, MZ202, MZ302) and the memory gate electrode MG are moved to the memory gate electrode MG. Thus, in the present embodiment, in the gate insulating film of the memory transistor, the film adjacent to the memory gate electrode MG is formed of an insulating film MZ4 formed of a silicon oxide film or a silicon oxynitride film that is difficult to trap charges, thereby improving the retention property of the memory element. Therefore, it is possible to improve the performance of the semiconductor device having a memory element.

Further, in the present embodiment, the memory element has a band structure such that a phenomenon in which the charges (here, electrons) is hardly removed from the charge storage film (the insulating film MZ2) to the memory gate electrode MG passing through the charge block film, which also contributes to the improvement of the retention characteristic of the memory element. This will be explained below.

In the first study example, since only the insulating film MZ103 is present between the charge accumulation film (insulating film MZ102) and the memory gate electrode MG, as can be seen from FIG. 20, in the charge block film between the charge accumulation film (insulating film MZ102) and the memory gate electrode MG (here the insulating film MZ103), the band gap is substantially constant, therefore, the energy level of the conduction band is substantially constant.

Further, in the case of the second examination example, the insulating films MZ203, MZ204, MZ205 are present between the charge storage film (insulating film MZ202) and the memory gate electrode MG. Therefore, in the case of the second study example, as can be seen from FIG. 22, in the charge block film between the charge accumulation film (insulating film MZ202) and the memory gate electrode MG (here the insulating films MZ203, MZ204, MZ205), the band gap is once larger in the insulating film MZ204 than in the insulating film MZ203, again it is smaller in the insulating film MZ205. Therefore, the energy level of the conduction band becomes higher once at the insulating film MZ204 than at the insulating film MZ203, but it is again lower at the insulating film MZ205.

Further, in the case of the third examination example, the insulating films MZ304, MZ303 are present between the charge storage film (insulating film MZ302) and the memory gate electrode MG. Therefore, in the case of the third study example, as can be seen from FIG. 24, in the charge block film between the charge storage film (insulating film MZ102) and the memory gate electrode MG (here, the insulating films MZ304, MZ303), the band gap is smaller in the insulating film MZ303 than in the insulating film MZ304. Therefore, the energy level of the conduction band is also lower in the insulating film MZ303 than in the insulating film MZ304.

In contrast, in the present embodiment, the insulating films MZ3, MZ4 are present between the charge storage film (insulating film MZ2) and the memory gate electrode MG, the band gap is larger in the insulating film MZ3 than in the insulating film MZ3, and larger in the insulating film MZ4 than in the insulating film MZ3. That is, as can be seen from FIG. 4, in the charge block film between the charge storage film (insulating film MZ2) and the memory gate electrode MG (here, the insulating films MZ3, MZ4), the band gap is larger in the insulating film MZ4 than in the insulating film MZ3, the energy level of the conductive band is also higher in the insulating film MZ4 than in the insulating film MZ3. That is, in the present embodiment, as can be seen from FIG. 4, in the charge block film between the charge accumulation film (insulating film MZ2) and the memory gate electrode MG (here, the insulating films MZ3, MZ4), the band gap is gradually (stepwise) increased, therefore, the energy level of the conduction band is also gradually (stepwise) increased. In the charge block film between the charge storage film and the memory gate electrode MG, the band structure such that the band gap gradually increases (stepwise) is considered to be a band structure such that such a phenomenon of passing of charges through the charge block film from the charge storage film and escapes into the memory gate electrode MG is less likely to occur. That is, in the charge block film between the charge storage film and the memory gate electrode MG, as compared with the band structure such that the band gap is gradually (stepwise) reduced, in the band gap is gradually (stepwise) larger, it is considered that such the phenomenon less likely occur that escaping of charges through the charge block film from the charge storage film to the memory gate electrode MG. In the present embodiment, from the viewpoint of the band structure, it is difficult to have a phenomenon in which charges are moved from the charge storage film (insulating film MZ2) to the memory gate electrode MG passing through the charge block film, and therefore it is possible to improve the retention properties of the memory element.

In this embodiment, as an insulating film interposed between the insulating film MZ3 and the memory gate electrode MG, it is desirable to select a material having a capability of trapping charges is low and having a larger band gap than the insulating film MZ3, and in this respect, silicon oxide film or silicon oxynitride film is suitable as the insulating film MZ4.

In the case of the present embodiment, it was confirmed by experiments that the retention characteristics of the memory element can be improved as compared with the first study example, the second study example, and the third study example. Further, in the case of the present embodiment, it was confirmed by experiments that the programming characteristic and the erasing characteristic were substantially equivalent to those of the first study example, the second study example, and the third study example. Therefore, in the present embodiment, retention characteristics can be improved while maintaining programming characteristics and erasing characteristics.

Further, in the present embodiment, on the side wall (side surface) of the memory gate electrode MG, the sidewall insulating film SP is formed, and the sidewall insulating film SP is composed of a stacked film having a silicon oxide film OX and a silicon nitride film NT, the silicon oxide film OX being adjacent to the memory gate electrode MG. The silicon nitride film NT is formed on the silicon oxide film NT. A thickness of the silicon oxide film OX is preferably 5 nm or more.

Since the silicon oxide film OX forming the side wall insulating film SP is adjacent to the memory gate electrode MG, an end portion of the insulating film MZ interposed between the memory gate electrode MG and the semiconductor substrate SB is adjacent to the silicon oxide film OX, and is covered with the silicon oxide film OX. For this reason, the end portion of the insulating film MZ2 which is the charge-storage film is also adjacent to the silicon oxide film OX and is covered with the silicon oxide film OX. A band gap of the silicon oxide film OX is larger than the band gap of the insulating film MZ2. The silicon oxide film is suitable for the charge block film which confines the charges in the charge accumulation film. Therefore, by providing the silicon oxide film OX so as to be adjacent to the memory gate electrode MG, the silicon oxide film OX covers the end portion of the insulating film MZ2 that is a charge accumulation film, it becomes possible to more accurately suppress or prevent the charges accumulated in the insulating film MZ2 from escaping from the end portion of the insulating film MZ2 to the outside the insulating film MZ2. As a result, the retention characteristic of the memory element can be further improved. From this viewpoint, it is preferable that the thickness of the silicon oxide film OX is 5 nm or more, whereby it is possible to accurately obtain effects of preventing charges accumulated in the insulating film MZ2 from escaping from the end portion of the insulating film MZ2 to the outside of the insulating film MZ2 by the presence of the silicon oxide film OX.

In addition, when the silicon nitride film NT is not formed on the silicon oxide film OX, oxygen may pass through the silicon oxide film OX and is supplied to the charge storage film (here, the insulating film MZ2) during the manufacturing process of the semiconductor device, which may change the properties of the charge storage film (insulating film MZ2). This may cause deterioration of the characteristics (e.g., I-V characteristics) of the memory element. Further, it may be a factor that causes variations (fluctuations) in the characteristics of the memory element. In the present embodiment, since the silicon nitride film NT is formed on the silicon oxide film OX, the silicon nitride film NT can function as a barrier film for oxygen diffusion. By the silicon nitride film NT present on the silicon oxide film OX, during the manufacturing process of the semiconductor device, since the passing of oxygen through the silicon oxide film OX and supplying of oxygen to the charge accumulation film (here the insulating film MZ2) can be suppressed or prevented, it is possible to suppress or prevent, changes in the property of the charge accumulation film (insulating film MZ2). This can suppress or prevent deterioration of the characteristics (e.g., I-V characteristics) of the memory element. In addition, variations in characteristics of the memory element can be suppressed or prevented. Therefore, the performance and reliability of the semiconductor device including the memory element can be improved.

<Modifications>

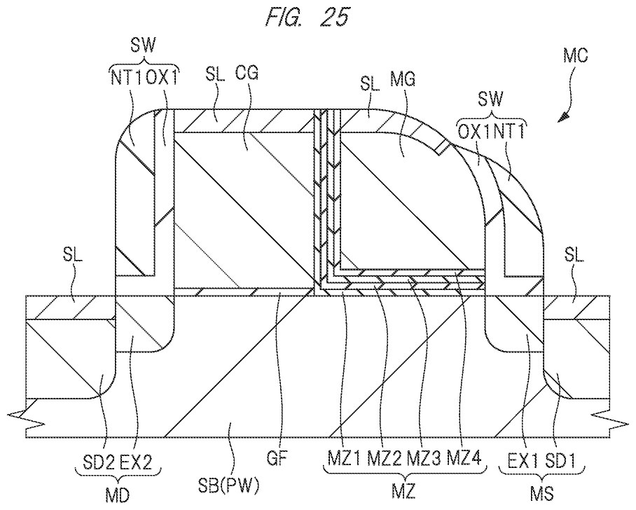

FIG. 25 is a cross-sectional view of a main part showing a modification example of the semiconductor device of the present embodiment, and corresponds to FIG. 2. In FIG. 25, the insulating film IL1, IL2 and the plug PG and the wire M1 shown in FIG. 1 are not illustrated.

Different point in the semiconductor device (memory element) of the modified example shown in FIG. 25 from the semiconductor device (memory element) of FIG. 2 will be described below.

In the case of the modification example shown in FIG. 25, the insulating film MZ is formed between the memory gate electrode MG and the semiconductor substrate SB3 (p-type well PW), and between the memory gate electrode MG and the control gate electrode. Therefore, in the case of the modification example shown in FIG. 25, the sidewall insulator SP is not formed, and the insulating film MZ is interposed between the memory gate electrode MG and the control gate electrode. The point that the insulating film MZ is formed of a stacked film of the insulating films MZ1, MZ2, MZ3, MZ4 is the same as in the case of FIG. 2 and also in the case of the modification example shown in FIG. 25. Further, in the case of the above-described FIG. 2, the control gate electrode CG is formed in a sidewall spacer shape via the sidewall insulating film SP on one sidewall of the memory gate electrode MG, in the case of the modification example of FIG. 25, the memory gate electrode MG is formed in a sidewall spacer shape via an insulating film MZ on one side wall of the control gate electrode CG. Further, in the case of FIG. 25, the sidewall spacer SW is formed of a stacked film of a silicon oxide film OX1 and a silicon nitride film NT1, and the silicon oxide film OX1 is adjacent to the control gate electrode CG or the memory gate electrode MG. Since the sidewall spacer SW is formed on the side wall of the control gate electrode CG and the memory gate electrode MG (side wall of the side not facing each other), it can also be regarded as a sidewall insulating film.

In the manufacturing process in the case of FIG. 2 above, after forming the insulating film MZ and the memory gate electrode MG previously, the insulating film GF and the control gate electrode CG are formed. In the manufacturing process in the case of FIG. 25, after forming the insulating film GF and the control gate electrode CG first, the insulating film MZ and the memory gate electrode MG are formed. Specifically, when manufacturing the memory element of FIG. 25, after forming the insulating film GF and the silicon film (silicon film for the control gate electrode CG) on the semiconductor substrate SB, by patterning the silicon film, the control gate electrode CG is formed. Then, on the semiconductor substrate SB, after forming an insulating film MZ so as to cover the control gate electrode CG, after forming a silicon film (silicon film for memory gate electrode MG) on the insulating film MZ, by etching back the silicon film, a memory gate electrode MG1 is formed. Afterwards, n− type semiconductor regions EX1, EX2 are formed by ion injection, the sidewall spacer SW is formed, and the n+ type semiconductor regions SD1, SD2 are formed by ion injection.

Also in the modified example shown in FIG. 25, similarly to the case of FIG. 2 above, by the insulating film MZ that is a gate insulating film of the memory transistor and a stacked film of the insulating films MZ1, MZ2, MZ3, MZ4, it is possible to improve the retention properties of the memory element.

While the invention made by the inventors of the present invention has been described specifically based on the embodiment, the present invention is not limited to the embodiment and it is needless to say that the invention can be variously modified within the scope of the invention.

1. A semiconductor device comprising:
a semiconductor substrate;
a first gate insulating film for a memory element formed on the semiconductor substrate;
a first gate electrode for the memory element formed on the first gate insulating film,
wherein the first gate insulating film includes a first insulating film, a second insulating film on the first insulating film, a third insulating film on the second insulating film, and a fourth insulating film on the third insulating film,
the second insulating film is formed of a high dielectric constant material containing hafnium and oxygen and has a charge accumulation function,
each band gap of the first insulating film and the third insulating film is larger than a band gap of the second insulating film,
the third insulating film is formed of a high dielectric constant material containing a metal element and oxygen,
the fourth insulating film is a silicon oxide film or a silicon oxynitride film, and is adjacent to the first gate electrode.

2. The semiconductor device according to claim 1,
wherein the third insulating film is an aluminum oxide film, an aluminum oxynitride film, or an aluminum silicate film.

3. The semiconductor device according to claim 1,
wherein the third insulating film is an aluminum oxide film.

4. The semiconductor device of claim 1,
wherein the second insulating film is a hafnium oxide film or a hafnium silicate film.

5. The semiconductor device according to claim 1,
wherein a band gap of the fourth insulating film is larger than the band gap of the third insulating film, Semiconductor equipment.

6. The semiconductor device according to claim 1,
wherein the third insulating film is a polycrystalline film.

7. The semiconductor device according to claim 6,
wherein the fourth insulating film is an amorphous film in the semiconductor device.

8. The semiconductor device according to claim 1
further comprising a sidewall insulating film formed on a sidewall of the first gate electrode.

9. The semiconductor device according to claim 8,
wherein the sidewall insulating film is formed of a stacked film including a silicon oxide film and a silicon nitride film, and
the silicon oxide film is adjacent to the first gate electrode.

10. The semiconductor device according to claim 9,
wherein a thickness of the silicon oxide film is 5 nm or larger.

11. The semiconductor device according to claim 8 further comprising:
a second gate insulating film for the memory element formed on the semiconductor substrate; and
a second gate electrode for the memory element formed on the second gate insulating film,
wherein the first gate electrode and the second gate electrode are adjacent via the side wall insulating film.

12. The semiconductor device according to claim 1 further comprising:
a second gate insulating film for the memory element formed on the semiconductor substrate; and
a second gate electrode for the memory element formed on the second gate insulating film,
wherein the first gate insulating film is also formed between the first gate electrode and the second gate electrode.
